(19) United States
(12) Patent Application Publication
(10) Pub. No.: US 2014/0160644 A1
(43) Pub. Date: Jun. 12, 2014

(54) COIL COMPONENT AND DISPLAY DEVICE INCLUDING THE SAME

(71) Applicant: SAMSUNG ELECTRO-MECHANICS CO., LTD., Suwon (KR)

(72) Inventors: Ki Hung NAM, Suwon (KR); Duck Jin AN, Suwon (KR); Soon Young KWON, Suwon (KR)

(73) Assignee: SAMSUNG ELECTRO-MECHANICS CO., LTD., Suwon (KR)

(21) Appl. No.: 13/770,898

(22) Filed: Feb. 19, 2013

(30) Foreign Application Priority Data
Dec. 7, 2012 (KR) 10-2012-0142152

(51) Int. Cl. H01F 30/06; H05K 7/00

(52) U.S. Cl. CPC H01F 30/06; H05K 7/00
USPC 361/679.01; 336/221; 336/212

(57) ABSTRACT

There are provided a coil component capable of easily mounting in a narrow mounting space, and a display device including the same. The coil component including: a bobbin including a cylindrical body part having a plurality of coils wound on an outer peripheral surface thereof, flange parts formed at both ends of the body part, and at least one or more core support parts protruded from outer surfaces of the flange parts; and a core coupled to the bobbin and seated on and fixed to the core support part.

### CROSS-REFERENCE TO RELATED APPLICATIONS

This application claims the priority of Korean Patent Application No. 10-2012-0142152 filed on Dec. 7, 2012, in the Korean Intellectual Property Office, the disclosure of which is incorporated herein by reference.

### BACKGROUND OF THE INVENTION

1. Field of the Invention

The present invention relates to a coil component, and more particularly, a coil component capable of being mounted in a narrow mounting space and a display device including the same.

2. Description of the Related Art

Various kinds of power supplies are required in various electronic devices such as a television (TV), a monitor, a personal computer (PC), an office automation (OA) device, and the like. Therefore, these electronic devices generally include a power supply and an adaptor converting externally-supplied alternating current (AC) power into power required for each electronic appliance.

Among the power supplies, a power supply using a switching mode (for example, a switch mode power supply (SMPS)) has recently been mainly used. This SMPS basically includes a switching transformer.

Generally, in a switching transformer, a core and a bobbin may have a significantly reduced size as compared to the case of a general transformer. In addition, a switching transformer may stably support the supply of low voltage and low current direct current (DC) power to the electronic appliance. Therefore, switching transformers have been widely used in electronic appliances that have tended to be miniaturized.

However, electronic devices have recently been miniaturized and therefore, adaptors and power supplies have also been manufactured to be compact. Therefore, a space in which electronic components are mounted has also been narrowed. Therefore, a switching transformer having a small size or a narrow width is required.

In addition, a switching transformer according to the related art generally has a tolerance in order to allow a core and a bobbin to be easily assembled. Due to this tolerance, even when the core is coupled to the bobbin, motion may be generated in the core. Therefore, different degrees of leakage inductance may be generated in the same product.

### RELATED ART DOCUMENT

(Patent Document 1) Korean Patent Laid-Open Publication No. 2006-0005300

### SUMMARY OF THE INVENTION

An aspect of the present invention provides a coil component capable of being mounted in a narrow mounting space and a display device including the same.

Another aspect of the present invention provides a coil component capable of fixing a movement of a core coupled to a bobbin and a display device including the same.

According to an aspect of the present invention, there is provided a coil component, including: a bobbin including a cylindrical body part having a plurality of coils wound on an outer peripheral surface thereof, flange parts formed at both ends of the body part, and at least one or more core support parts protruded from outer surfaces of the flange parts; and a core coupled to the bobbin and seated on and fixed to the core support part.

The core may include: a first leg inserted into a through-hole of the body part; a second leg disposed outside the body part; and a connection part connecting the first leg and the second leg.

The second leg may be formed to have a width wider than that of the first leg.

The connection part may have a width increased in a direction toward the second leg.

The second leg may be disposed above an upper portion of the bobbin.

The second leg may be disposed to entirely cover the upper portion of the bobbin.

The second leg may have a concave inner surface, corresponding to a shape of the bobbin facing the second leg.

The core support parts may be respectively disposed on both sides of the body part based on the body part.

The core support parts may include a supporting surface formed to be inclined to contact and support the core.

The core support parts may guide the core to be disposed at a center of the through-hole using gravity.

The core support part may support a portion of the core exposed outwardly of the body part.

The body part may have an oval cross-sectional shape elongated in a vertical direction.

The bobbin may include a terminal connection part extended from the flange part.

The core may be configured as a pair of U-shaped cores.

The core may be coupled to the bobbin so as to be spaced apart from an inner surface of the cylindrical body part.

The bobbin may include at least one or more partition walls partitioning a space in which the coil is wound into a plurality of spaces in a length direction of the body part.

According to another aspect of the present invention, there is provided a coil component, including: a bobbin including a cylindrical body part having a plurality of coils wound on an outer peripheral surface thereof; and a core having a first leg inserted into the body part, wherein the first leg is disposed to be spaced apart from an inner surface of the body part.

According to another aspect of the present invention, there is provided a coil component, including: a core; and a bobbin including a cylindrical body part having a plurality of coils wound on an outer peripheral surface thereof and having the core inserted thereinto and a core support part supporting the core outside the body part, wherein a movement of the core is fixed in a horizontal direction and in a downward direction by the core support part.

According to another aspect of the present invention, there is provided a display device, including: a power supply having the at least one coil component as described above mounted on a substrate; and a display panel receiving power from the power supply.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a perspective view schematically showing a coil component according to an embodiment of the present invention;

FIG. 2 is an exploded perspective view of FIG. 1;

FIG. 3 is a side view of the coil component of FIG. 1;

FIGS. 4 and 5 are side views of a bobbin of FIG. 2;

FIG. 6 is a view illustrating a coil component according to an embodiment of the present invention;

FIG. 7 is a view showing a bobbin according to another embodiment of the present invention; and

FIG. 8 is an exploded perspective view schematically showing a display device according to an embodiment of the present invention.

### DETAILED DESCRIPTION OF THE EMBODIMENTS

Hereinafter, embodiments of the present invention will be described in detail with reference to the accompanying drawings.

The invention may, however, be embodied in many different forms and should not be construed as being limited to the embodiments set forth herein. Rather, these embodiments are provided so that this disclosure will be thorough and complete, and will fully convey the scope of the invention to those skilled in the art.

In the drawings, the shapes and dimensions of elements may be exaggerated for clarity, and the same reference numerals will be used throughout to designate the same or like elements.

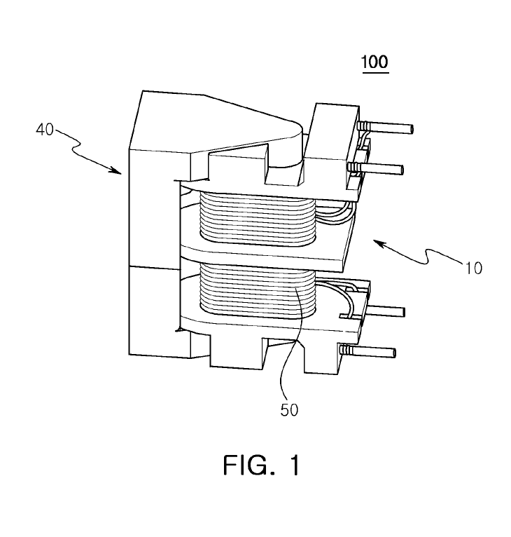

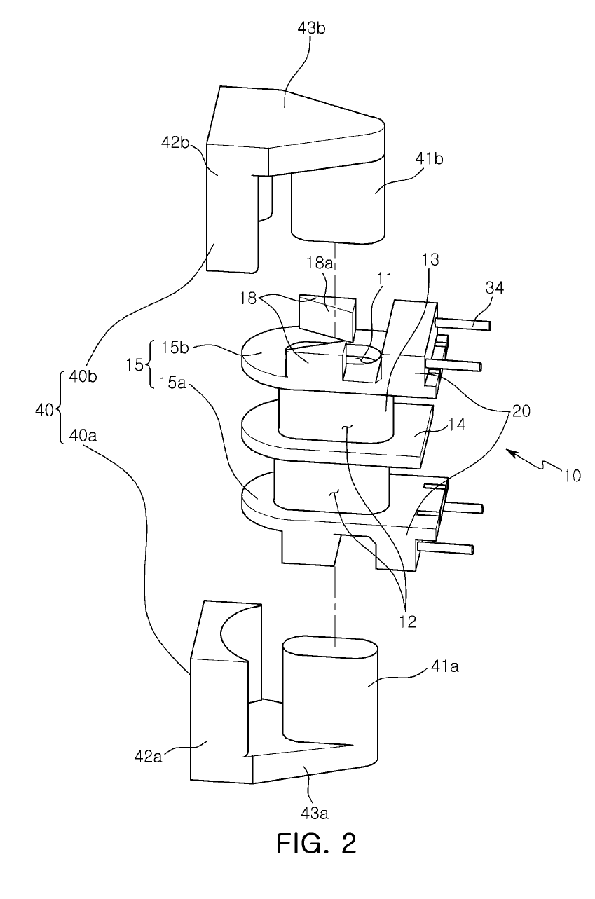

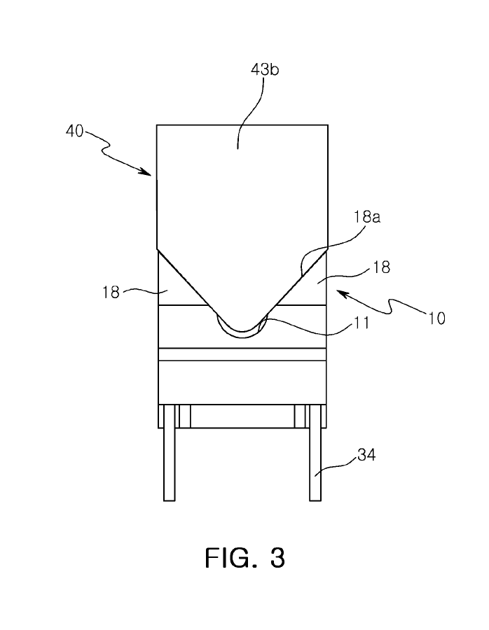

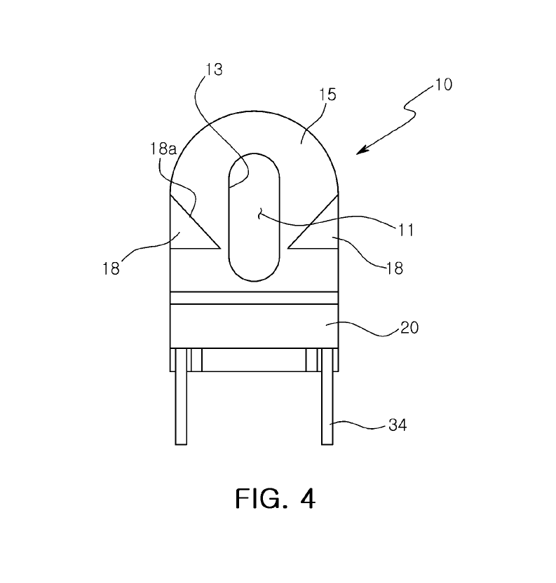

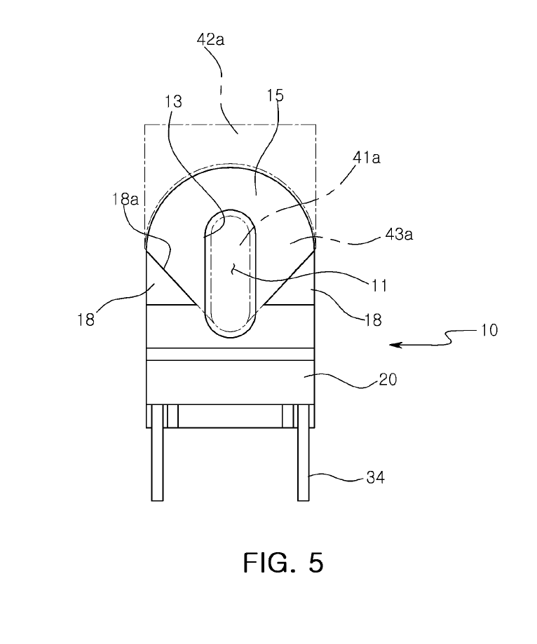

FIG. 1 is a perspective view schematically showing a coil component according to an embodiment of the present invention and FIG. 2 is an exploded perspective view of FIG. 1. In addition, FIG. 3 is a side view of the coil component of FIG. 1 and FIGS. 4 and 5 are side views of a bobbin of FIG. 2. Here, FIG. 5 is a view showing the core coupled to the bobbin. In addition, the coil is omitted in FIGS. 2 and 3 for convenience of explanation.

Referring to FIGS. 1 through 5, a coil component 100 according to an embodiment of the present invention may be an insulating type switching transformer mounted in a switch mode power supply (SMPS), an adapter, or the like, and may include a bobbin 10, a core 40, and a coil 50.

The bobbin 10 may form an entire body of the coil component. The bobbin 10 may be easily manufactured by injection molding, but is not limited thereto. In addition, the bobbin 10 according to the present embodiment may be formed of an insulating resin and be formed of a material having high heat resistance and high voltage resistance. As a material of the bobbin 10, for example, polyphenylenesulfide (PPS), liquid crystal polyester (LCP), polybutyleneterephthalate (PBT), polyethyleneterephthalate (PET), phenolic resin, and the like, may be used.

The bobbin 10 may include a winding part 12 having the coil 50 wound thereon and a terminal connection part 20 formed at one end of the winding part 12.

The winding part 12 may include a body part 13 having a cylindrical shape and a flange part 15 extended from both ends of the body part 13 in an outer diameter direction.

An inner portion of the body part 13 may be provided with a through-hole 11 into which a portion of the core 40 is inserted. In the present embodiment, the through-hole 11 may be formed to have an oval shape (or a shape in which corner portions of a rectangular are rounded in a curved manner) elongated in a vertical direction. This configuration allows the coil component 100 according to the present embodiment to have a narrow width. Therefore, the present invention is not limited thereto, but may be changed as needed.

The coil 50 is wound on an outer surface of the body part 13. The body part 13 may include at least one partition wall 14 formed on the outer peripheral surface thereof, and the partition wall 14 partitions a space in a length direction of the body part 13. In this configuration, the coil 50 may be wound in each of the spaces partitioned by the partition wall 14.

The winding part 12 according to the present embodiment may include a single partition wall 14. Therefore, the winding part 12 according to the present embodiment may include two partitioned spaces. However, the present invention is not limited thereto. That is, a plurality of spaces may be formed through a plurality of partition walls as needed.

Meanwhile, although the case in which the partition wall 14 is formed integrally with the bobbin 10 is described by way of example in the present embodiment, the present invention is not limited thereto, but may be variously modified. For example, the partition wall 14 may also be formed as a separate member and be then coupled to the bobbin 20.

The flange part 15 may protrude and to be extended from both ends, that is, upper and lower ends, of the body part 13 in the outer diameter direction. The flange part 15 according to the present embodiment may be divided into a first flange part 15a and a second flange part 15b according to a formation position thereof.

In addition, a space between the first and second flange parts 15a and 15b on the outer peripheral surface of the body part 13 may be used as a winding space in which the coil 50 is wound. Therefore, the flange part 15 may serve to protect the coil 50 from the outside and secure an insulation property therebetween, while supporting the coil 50 wound in the winding space at both sides thereof.

Particularly, the bobbin 10 according to the present embodiment includes a core support part 18 for supporting the core 40. The core support part 18 may be formed as a protrusion on the outer surface of the flange part 15.

The core support part 18 is included to stably support the core 40 when the core 40 is coupled to the bobbin 10. To this end, two core support parts 18 may be formed on one side of the flange part 15 (that is, a total of four core support parts 18) so that connection parts 43a and 43b of the core 40 are supported in both directions of the flange part 15. In addition, the two core support parts 18 formed on one side of the flange part 15 may be symmetrically disposed based on the through-hole 11.

In addition, each of the core support parts 18 may include a supporting surface 18a in contact with the core 40 to support the core 40.

The supporting surface 18a of the core support part 18 contacts the connection parts 43a and 43b of the core 40 and supports the core 40. The core support parts 18 may have a shape corresponding to the shape of the connection parts 43a and 43b so as to stably support the core 40.

In the present embodiment, the connection parts 43a and 43b of the core 40 may be formed to have a width increased in a direction toward second legs 42a and 42b, that is, in an upward direction thereof. Corresponding to the shape of the above-mentioned connection parts 43a and 43b, the two core support parts 18 facing each other may be formed in a shape in which an interval between the two core support parts is increased in a direction toward an upper portion of the supporting surface 18a according to the shape of the connection parts 43a and 43b of the core 40.

The terminal connection part 20 may be formed to be extended from the flange part 15. More specifically, the terminal connection part 20 according to the present embodiment may be formed on each of the flange parts 15a and 15b and may be protruded from lower portions of the flange parts 15a and 15b.

Meanwhile, referring to FIG. 2, since the terminal connection part 20 according to the present embodiment is partially extended from the flange part 15, it may be difficult to clearly distinguish between the flange part 15 and the terminal connection part 20. Therefore, the terminal connection part 20 according to the present embodiment may be perceived as a portion of the flange part 15.

The terminal connection part 20 may include a plurality of external connection terminals 34 connected thereto.

The core 40 may be partially inserted into the through-hole 11 formed in the bobbin 10 and be electromagnetically coupled to the coil 50 to form a magnetic path.

The core 40 according to the present embodiment may be provided in pair. The pair of cores 40 may be partially inserted into the through-hole 11 of the bobbin 10 to thereby be coupled to each other.

The core 40, which is a ferrite core formed to have an approximately U shape, may be used as a path of magnetic field generated according to flow of current in the coil.

The pair of cores 40a and 40b may be formed to have the same shape such that they are symmetrical to each other. In this case, the pair of cores 40 may be simply manufactured, and assembly thereof may be facilitated.

In addition, the pair of cores 40a and 40b includes first legs 41a and 41b and the second legs 42a and 42b, and the first legs 41a and 41b and the second legs 42a and 42b are connected by the connection parts 43a and 43b. The first legs 41a and 41b are coupled to face each other and the second legs 42a and 42b are coupled to face each other, thereby forming a continuous magnetic flux loop.

The first legs 41a and 41b are inserted into the through-hole 11 of the body part 13. Therefore, cross-sections of the first legs 41a and 41b may correspond to a cross-section of the through-hole 11 and the first legs 41a and 41b may have a cross-sectional area smaller than that of the through-hole 11 so as to be easily inserted into the through-hole 11.

In the present embodiment, the through-hole 11 has an oval-like cross-section. Therefore, the first legs 41a and 41b also have an oval-like cross-section.

Ends of the above-mentioned first legs 41a and 41b may face each other at a central portion of the through-hole 11 and may be coupled to each other.

The second legs 42a and 42b may be disposed in parallel with the body part 13 outside the bobbin 10. In addition, the second legs 42a and 42b according to the present embodiment may be formed to have a width wider than that of the first legs 41a and 41b.

More specifically, the second legs 42a and 42b may partially enclose the bobbin 10. In the present embodiment, the second legs 42a and 42b are disposed to entirely cover the upper portion of the bobbin 10.

To this end, inner surfaces of the second legs 42a and 42b, that is, surfaces thereof facing the bobbin 10 may be formed to correspond to the shape of the bobbin 10. In the present embodiment, the flange part 15 forming the upper portion of the bobbin 10 may be formed to have a semicircular (or an arc) shape. Therefore, the inner surfaces of the second legs 42a and 42b may be concavely formed to have the semicircular shape correspondingly.

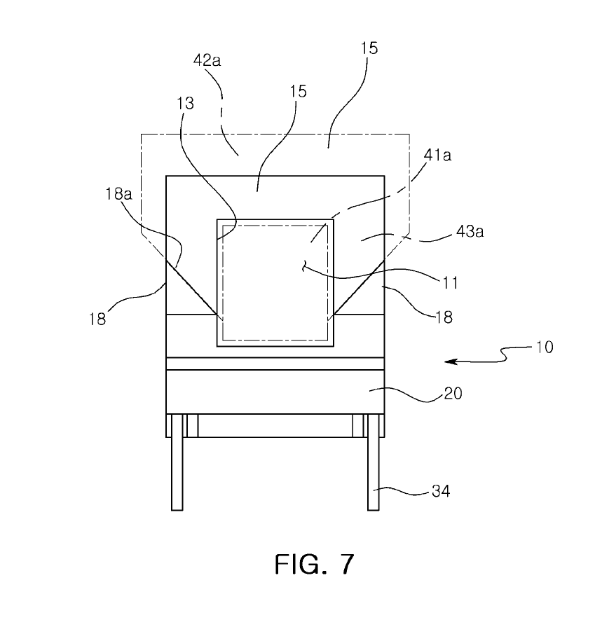

However, the present invention is not limited thereto, and in the case in which an upper end of the bobbin 10 is formed to have an angled shape, as shown in FIG. 7, the inner surfaces of the second legs 42a and 42b may also be formed to have the angled shape.

The shape of the second legs 42a and 42b is intended to shield electromagnetic wave introduced from the outside. That is, the coil component 100 according to the present embodiment may maximally block the electromagnetic wave introduced from the outside to the coil 50 through the second legs 42a and 42b by forming an external area of the second legs 42a and 42b as widely as possible.

The connection parts 43a and 43b may be used to make connection between the first legs 41a and 41b and the second legs 42a and 42b. As described above, the second legs 42a and 42b may be formed to have a width wider than that of the first legs 41a and 41b. Therefore, the connection parts 43a and 43b may be formed to be expanded in the direction toward the second legs 42a and 42b sides.

In addition, both sides of the connection parts 43a and 43b contact the supporting surface 18a of the core support part 18. That is, both sides of the connection parts 43a and 43b contact the supporting surface 18a of the core support part 18, such that the core 40 is seated on the core support part 18 by gravity, whereby movement of the core 40 is fixed.

The core 40 may be formed of Mn—Zn based ferrite having higher permeability, lower loss, higher saturation magnetic flux density, higher stability, and lower production cost, as compared to other materials. However, in the embodiment of the present invention, a material of the core 40 is not limited.

Meanwhile, in order to secure insulation properties between the coil 50 wound on the bobbin 10 and the core 40, an insulating cover (not shown) may be interposed between the bobbin 10 and the core 40.

The insulating cover may be interposed between the bobbin 10 and the core 40 corresponding to the entire inner surface of the core 40 facing the bobbin 10 or be partially interposed therebetween only where the coil 50 and the core 40 face each other.

As the insulating cover, a cover formed of an insulating tape or a resin material may be used. However, the present invention is not limited thereto.

The coil 50 may be wound on the winding part 12 of the bobbin 10 and include primary and secondary coils.

Each of the primary coil and the secondary coil may include a plurality of individual coils that are electrically insulated from each other. Here, the number of the primary and secondary coils may be appropriately changed as needed.

Each of the primary and the secondary coils according to the embodiment of the present invention may be wound in the winding space partitioned by the partition wall 14. Therefore, the insulation properties between the primary coil and the secondary coil may be secured by the partition wall 14.

As the coil 50 according to the present embodiment, a general insulated coil (for example, a polyurethane wire, or the like), and a coil formed by twisting several strands of wires (for example, a Litz wire, or the like) may be used. In addition, a multi-insulated coil (for example, a triple insulated wire (TIW), or the like) having high insulation properties may be used. That is, types of the coils may be selected as needed.

The coil component 100 according to the present embodiment configured as described above has the second legs 42a and 42b of the core 40 disposed above the upper portion of the bobbin 10, such that it may be manufactured to have a narrow width. Therefore, the coil component may also be easily mounted in a narrow mounting space.

In addition, in the coil component 100 according to the present embodiment, the core 40 disposed outside the bobbin 10 partially encloses the bobbin 10. Therefore, electromagnetic wave introduced into the bobbin 10 may be maximally blocked without any additional element.

In addition, the core 40 according to the present embodiment is supported by the core support part 18 formed on the bobbin 10, such that an interval between the bobbin 10 and the core 40 inserted into the bobbin may be equally maintained even when a plurality of coil components 100 are manufactured. A detailed description thereof will be provided below.

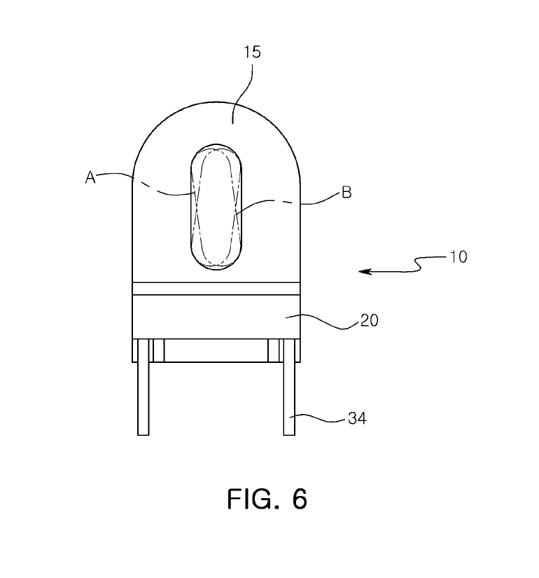

FIG. 6, a view illustrating a coil component according to an embodiment of the present invention, shows that the bobbin 10 has no core support part.

In order to easily insert the core 40 into the through-hole 11 of the bobbin 10, the core 40 inserted into the through-hole 11 needs to have a cross-sectional area smaller than that of the through-hole 11. Therefore, in the case in which the core support part 18 is omitted as shown in FIG. 6, the first legs 41a and 41b need to be supported by contacting the inner wall of the through-hole 11. In this case, the core 40 is coupled to the bobbin 10 while being tilted toward direction A or direction B.

That is, in the case in which the core support part 18 is not present, the core 40 of the coil component is fixed to the bobbin 10 in a state in which it is tilted toward the direction A or the direction B. Therefore, the interval between the core 40 and the coil 50 may be differently formed, such that the respective coil components 100 have different leakage inductance.

However, the coil component according to the present embodiment has the core 40 supported by the core support part 18. In addition, the core support part 18 supports the connection parts 43a and 43b rather than the first legs 41a and 41b.

Due to this configuration, the first legs 41a and 41b of the core 40 are always disposed at the same position (that is, the center of the through-hole) by the core support part 18 and the gravity without being tilted in a horizontal direction or a downward direction. Therefore, the core 40 according to the present embodiment may maintain a state in which the first legs 41a and 41b do not support or contact the inner wall of the through-hole 11, but are spaced apart from the inner wall of the through-hole by a predetermined interval, whereby a change or an increase in leakage inductance according to the position of the core may be minimized.

Meanwhile, the present invention is not limited to the above-mentioned configuration, but may be variously modified as needed.

FIG. 7 is a side view showing a bobbin according to another embodiment of the present invention, corresponding to FIG. 5.

Referring to FIG. 7, in the coil component according to the present embodiment, the through-hole 11 of the bobbin 10 has a rectangular cross-section, and the first legs 41a of the core 40 also have a rectangular cross-section.

In addition, the core 40 has the connection part 43a seated on the core support part 18 and is coupled to the bobbin 10.

As in the present embodiment, even in the case in which the through-hole 11 has the rectangular cross-section, an interval is generated between the first leg 41a of the core 40 and the through-hole 11 of the bobbin 10. Therefore, in the case in which the core support part 18 is not present, it is difficult for the core 40 to be fixed at an accurate position.

However, the coil component according to the present embodiment has the core 40 fixedly seated at the accurate position by the core support part 18, whereby a change in leakage inductance due to the movement of the core 40 may be minimized.

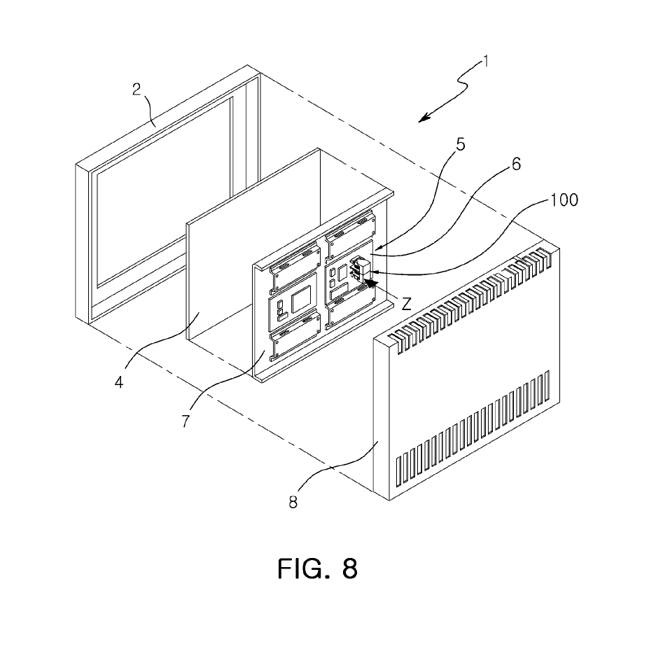

FIG. 8 is an exploded perspective view schematically showing a display device according to an embodiment of the present invention.

Referring to FIG. 8, a display device 1 according to the embodiment of the present invention may include a display panel 4, a power supply 5 having the coil component 100 mounted therein, and covers 2 and 8.

The covers 2 and 8 may include a front cover 2 and a back cover 8 and may be coupled to each other to thereby form a space therebetween.

The display panel 4 may be disposed in the internal space formed between the covers 2 and 8. As the display panel 4, various flat panel display panels such as a liquid crystal display (LCD), a plasma display panel (PDP), an organic light emitting diode (OLED), and the like, may be used.

The power supply (SMPS) 5 may provide power to the display panel 4. The power supply 5 may be formed by mounting a plurality of electronic components on a printed circuit board 6 and particularly, may include at least one of the coil components 100 according to the above-mentioned embodiments mounted therein.

The power supply 5 may be fixed to a chassis 7 and be fixedly disposed in the internal space formed between the covers 2 and 8 together with the display panel 4.

The coil component and the display device including the same are not limited to the above-described embodiments, and those skilled in the art will appreciate that various modifications, additions and substitutions are made, without departing from the scope and spirit of the invention.

In addition, in the above-described embodiment, the insulating type switching transformer has been described as an example of coil components. However, the present invention is not limited thereto, but may be variously applied to a component using a coil wound thereon such as a transformer for an inverter, a high frequency filter or the like, and an electronic device including the same.

As set forth above, in a coil component according to the embodiments of present invention, legs of a core disposed outside a bobbin are disposed above an upper portion of the bobbin, whereby the coil component may be manufactured to entirely have a narrow width. Therefore, the coil component may be easily mounted in a narrow mounting space.

In addition, since the core disposed outside the bobbin partially encloses the bobbin, electromagnetic wave introduced into the bobbin may be maximally blocked without any additional element.

In addition, the core is supported by a core support part formed on the bobbin, whereby the legs of the core do not support or contact an inner wall of a through-hole, but maintain a predetermined interval from the inner wall. Therefore, a change or increase in leakage inductance according to the position of the core may be minimized.

While the present invention has been shown and described in connection with the embodiments, it will be apparent to those skilled in the art that modifications and variations can be made without departing from the spirit and scope of the invention as defined by the appended claims.

What is claimed is:

1. A coil component, comprising:
a bobbin including a cylindrical body part having a plurality of coils wound on an outer peripheral surface thereof, flange parts formed at both ends of the body part, and at least one or more core support parts protruded from outer surfaces of the flange parts; and
a core coupled to the bobbin and seated on and fixed to the core support part.

2. The coil component of claim 1, wherein the core includes:
a first leg inserted into a through-hole of the body part;
a second leg disposed outside the body part; and
a connection part connecting the first leg and the second leg.

3. The coil component of claim 2, wherein the second leg is formed to have a width wider than that of the first leg.

4. The coil component of claim 3, wherein the connection part has a width increased in a direction toward the second leg.

5. The coil component of claim 2, wherein the second leg is disposed above an upper portion of the bobbin.

6. The coil component of claim 5, wherein the second leg is disposed to entirely cover the upper portion of the bobbin.

7. The coil component of claim 2, wherein the second leg has a concave inner surface, corresponding to a shape of the bobbin facing the second leg.

8. The coil component of claim 1, wherein the core support parts are respectively disposed on both sides of the body part based on the body part.

9. The coil component of claim 8, wherein the core support parts include a supporting surface formed to be inclined to contact and support the core.

10. The coil component of claim 8, wherein the core support parts guide the core to be disposed at a center of the body part using gravity.

11. The coil component of claim 8, wherein the core support parts support a portion of the core exposed outwardly of the body part.

12. The coil component of claim 1, wherein the body part has an oval cross-sectional shape elongated in a vertical direction.

13. The coil component of claim 1, wherein the bobbin includes a terminal connection part extended from the flange part.

14. The coil component of claim 1, wherein the core is configured as a pair of U-shaped cores.

15. The coil component of claim 1, wherein the core is coupled to the bobbin so as to be spaced apart from an inner surface of the cylindrical body part.

16. The coil component of claim 1, wherein the bobbin includes at least one or more partition walls partitioning a space in which the coil is wound into a plurality of spaces in a length direction of the body part.

17. A coil component, comprising:
a bobbin including a cylindrical body part having a plurality of coils wound on an outer peripheral surface thereof; and
a core having a first leg inserted into the body part,
wherein the first leg is disposed to be spaced apart from an inner surface of the body part.

18. A coil component, comprising:
a core; and
a bobbin including a cylindrical body part having a plurality of coils wound on an outer peripheral surface thereof and having the core inserted thereinto and a core support part supporting the core outside the body part,
wherein a movement of the core is fixed in a horizontal direction and in a downward direction by the core support part.

19. A display device, comprising:
a power supply having the at least one coil component of claim 1 mounted on a substrate; and
a display panel receiving power from the power supply.
